(19) United States
(12) Patent Application Publication
(10) Pub. No.: US 2020/0381271 A1
(43) Pub. Date: Dec. 3, 2020

(54) SYSTEM AND APPARATUS FOR ENHANCED SUBSTRATE HEATING AND RAPID SUBSTRATE COOLING

(71) Applicant: APPLIED Materials, Inc., Santa Clara, CA (US)

(72) Inventors: Dawei Sun, Nashua, NH (US); Dale K. Stone, Lynnfield, MA (US); D. Jeffrey Lischer, Gloucester, MA (US); Lyudmila Stone, Lynnfield, MA (US); Steven Anella, West Newbury, MA (US); Julian G. Blake, Gloucester, MA (US); Ron Serisky, Gloucester, MA (US); Daniel A. Hall, West Newbury, MA (US); Robert H. Bettencourt, Gloucester, MA (US)

(73) Assignee: APPLIED Materials, Inc., Santa Clara, CA (US)

(21) Appl. No.: 16/560,326

(22) Filed: Sep. 4, 2019

Related U.S. Application Data
(60) Provisional application No. 62/853,324, filed on May 28, 2019.

(51) Int. Cl. H01L 21/67; H05B 1/02

(52) U.S. Cl. CPC H01L 21/67109; H05B 2214/04; H05B 1/0233; H01L 21/67115

(57) ABSTRACT

A heating system for heating a substrate. The heating system may include a susceptor, where the susceptor has a substrate support surface. The heating system may further include a heat transfer layer, disposed on the substrate support surface, where the heat transfer layer comprising an array of aligned carbon nanotubes.

### RELATED APPLICATIONS

This application claims priority to U.S. Provisional Patent Application No. 62/853,324, filed May 28, 2019, entitled SYSTEM AND APPARATUS FOR ENHANCED SUBSTRATE HEATING AND RAPID SUBSTRATE COOLING, and incorporated by reference in its entirety.

### FIELD

This disclosure relates to substrate processing. More particularly, the present disclosure relates to improved heating and cooling of a substrate during substrate processing.

### BACKGROUND

Substrate processing for making electrical devices, electronic devices, optical devices, mechanical devices, and so forth, may entail operations such as layer deposition, substrate etching, ion implantation, annealing, or other processes, where heating and cooling of a substrate takes place. Many types of processing systems employ resistive heating, where a substrate is placed in contact with a substrate holder of a platen directly or indirectly resistively heated. Heat is then conducted from the platen or holder to the substrate. Other types of processing systems may employ lamp heating, such as halogen lamps, to heat a substrate primarily by radiation.

When substrates are processed under vacuum or reduced pressure below atmospheric pressure, thermal conduction decreases between a heated platen or holder and a substrate, as compared to thermal conduction at atmospheric pressure. Thus, heating of a substrate using a heated platen or holder may be sluggish for processed at reduced pressure of under vacuum.

Likewise, radiative heating of substrates may be inefficient for many types of substrates due to the low absorbance of the substrate. For example, silicon wafers are semitransparent to infrared radiation, such as radiation emitted by halogen lamps at substrate temperatures below approximately 500° C. Moreover, other substrates remain highly transparent to radiation including infrared radiation up to much higher temperatures. Accordingly, lamp heating of substrates may be inefficient and result in sluggish heating rates.

Regarding substrate cooling, once substrate processing at elevated temperatures is completed, relatively rapid cooling of the substrate to lower temperature such as room temperature may be useful to increase throughput and reduce overall process time. Effectively cooling substrates such as semiconductor wafers (wafers) in a vacuum environment is challenging due to the poor thermal contact between the wafer and surroundings. Due to metal contamination and particle generation concerns, the use of thermal gaskets or other mechanical means to increase thermal contact conductance (TCC) or simply, “thermal conductance,” from a substrate is not widely deployed. Even using electrostatic clamping and backside gas cooling yields an effective TCC is estimated to be less than 1000 W/m²-K, a thermal conductance not sufficient to generate very rapid substrate cooling. One approach for wafer cooling is to transfer a wafer from vacuum in a processing chamber to a loadlock, where the loadlock is maintained under atmospheric pressure, and to accordingly cool the wafer using natural convection. Under this approach, as an example, approximately 12 minutes may be required to cool a Si wafer from 150° C. to 60° C. In addition, the wafer may endure >10° C. temperature differential during cooling.

With respect to these and other considerations the present disclosure is provided.

### BRIEF SUMMARY

In one embodiment A heating system for heating a substrate is provided. The heating system may include a susceptor, where the susceptor has a substrate support surface. The heating system may further include a heat transfer layer, disposed on the substrate support surface, where the heat transfer layer comprising an array of aligned carbon nanotubes.

In a further embodiment, a cooling apparatus for cooling a substrate may include a cooling block. The cooling block may include a housing, where the housing has a substrate support surface. The cooling block may also include a phase change component, disposed within the housing, and a heat transfer layer, disposed on the substrate support surface, the heat transfer layer comprising an array of aligned carbon nanotubes.

In another embodiment, a cooling system for cooling a substrate may include a cooling block. The cooling block may include a housing, having a substrate support surface and a lower surface, opposite the substrate support surface. The cooling block may also include a phase change component, disposed within the housing. The cooling system may also include a first heat transfer layer, disposed on the substrate support surface, where the first heat transfer layer includes a first array of aligned carbon nanotubes. The cooling system may include a cooling structure, disposed opposite the lower surface, and a second heat transfer layer, disposed in contact with the lower surface and the cooling structure, where the second heat transfer layer includes a second array of aligned carbon nanotubes.

### BRIEF DESCRIPTION OF THE DRAWINGS

FIG. 1A depicts a heating apparatus, in accordance with embodiments of the disclosure;

FIG. 1B depicts physical properties of a silicon substrate at room temperature;

FIG. 1C depicts another heating apparatus, in accordance with embodiments of the disclosure;

FIG. 2 depicts a cooling apparatus, in accordance with embodiments of the disclosure;

FIG. 3A depicts a cooling system, in accordance with embodiments of the disclosure; and

FIG. 3B depicts another cooling system, in accordance with embodiments of the disclosure.

### DETAILED DESCRIPTION

The present embodiments will now be described more fully hereinafter with reference to the accompanying drawings, where various embodiments are shown. The subject of this disclosure, however, may be embodied in many different forms and should not be construed as limited to the embodiments set forth herein. Rather, these embodiments are provided so this disclosure will be thorough and complete, and will fully convey the scope of the subject of this disclosure to those skilled in the art. In the drawings, like numbers refer to like elements throughout.

In the following description and/or claims, the terms “on,” “overlying,” “disposed on” and “over” may be used in the following description and claims. “On,” “overlying,” “disposed on” and “over” may be used to indicate where two or more elements are in direct physical contact with each other. However, “on,”, “overlying,” “disposed on,” and over, may also mean where two or more elements are not in direct contact with each other. For example, “over” may mean where one element is above another element but not contact each other and may have another element or elements in between the two elements. Furthermore, the term “and/or” may mean “and”, it may mean “or”, it may mean “exclusive-or”, it may mean “one”, it may mean “some, but not all”, it may mean “neither”, and/or it may mean “both”, although the scope of claimed subject matter is not limited in this respect.

Various embodiments involve apparatus and systems to rapidly heat as well as rapidly cool a substrate, including under vacuum conditions. The term “elevated temperature” as used herein, refers to substrate temperatures generally greater than approximately 50° C. Various embodiments are particularly useful for heating and cooling substrates when disposed in an atmosphere below ambient pressure, such as below 100 Torr, below 1 Torr, or below 1 mTorr pressure. Accordingly, the present embodiments provide enhanced thermal coupling between a temperature sensor and substrate via improved thermal and mechanical properties of a thermal transfer layer.

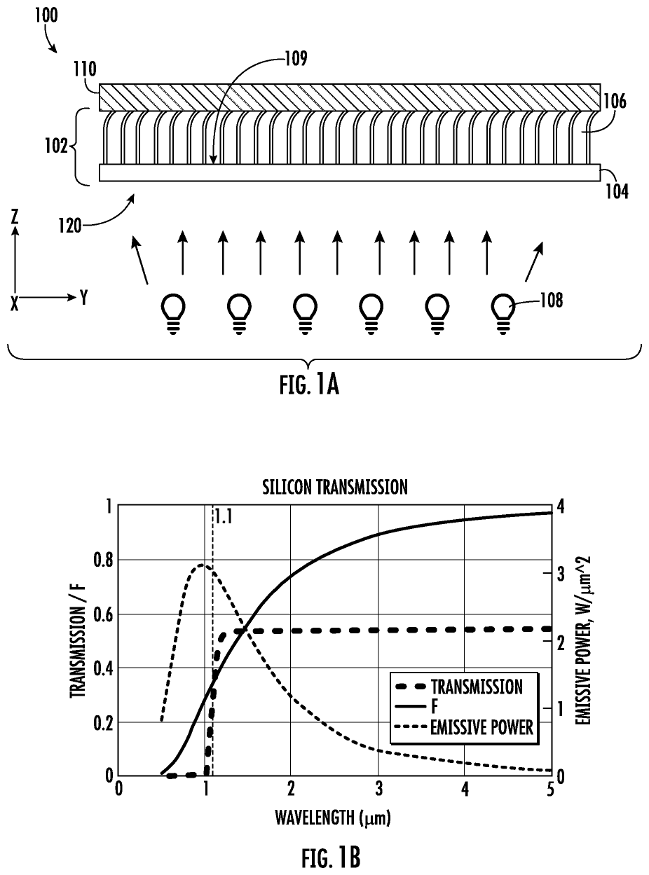

FIG. 1 depicts a heating apparatus 100, in accordance with embodiments of the disclosure. The heating apparatus 100 may include a heat transfer assembly 102, including a susceptor 104 and a heat transfer layer 106. The susceptor 104 may have a substrate support surface 109, where the heat transfer layer 106 is disposed on the substrate support surface 109. According to various embodiments of the disclosure, the heat transfer layer 106 includes an array of aligned carbon nanotubes.

The susceptor 104 may be constructed of a known material, such as a ceramic, graphite or a metallic material. In various non-limiting embodiments, over a given operating range, such as room temperature to 500° C. or room temperature to 1000 C, the susceptor material used to form susceptor 104 may be an opaque material to radiation such as infrared radiation, and may have a high emissivity.

The heat transfer assembly 102 may be designed to abut against a substrate, such as substrate 110. The substrate 110 may be a flat body, such as a wafer or plate, where the substrate defines a substrate plane coincident with or parallel to the X-Y plane of the Cartesian coordinate system shown. The susceptor 104 may also have a flat surface, and in some embodiments may extend over an area matching or exceeding the area of the substrate 110 within the X-Y plane. According to various embodiments of the disclosure, the array of aligned carbon nanotubes within the heat transfer layer 106 extend along an alignment direction, perpendicular to the substrate plane, meaning along the Z-axis, forming a layer of vertical array of carbon nanotubes (VACNT). The heat transfer layer 106 may be formed wherein the carbon nanotubes are formed as a growing layer of vertically aligned nanotubes on the susceptor 104 or may be formed by applying a pre-formed layer of vertically aligned nanotubes onto the susceptor 104.

As shown in FIG. 1, the heating apparatus 100 further includes a heating assembly 108, disposed to heat the susceptor 104 from a side 120 of the susceptor, opposite the substrate support surface 109. The heating assembly 108 may include known heating components, such as a resistive heater or an array of lamps (as pictured). Thus, in some embodiments, the heating assembly 108 may not be in physical contact with the susceptor 104.

There are multiple advantages provided by the arrangement of FIG. 1, including the ability to absorb the incoming thermal energy by the susceptor 104, and the efficient heat transfer between the susceptor 104 and the substrate 110, enabled by the VACNT coating.

Notably, known halogen lamp heating of a Si wafer is not efficient due to the nature of the silicon material. Silicon is largely semitransparent in the infrared range (above ˜1 μm wavelength), as shown is shown in FIG. 1B (red line). The spectral blackbody emissive power (peaked curve), and fractional blackbody function of a 3000K heat source (curve increasing from left to right) is also shown in FIG. 1B. The fractional blackbody function is defined as

$${F}_{{λ}_{1} T \to {λ}_{1} T} = \frac{{\int }_{{λ}_{1}}^{{λ}_{2}} {E}_{λ b} ( T ) d λ}{σ {T}^{4}} = {F}_{0 \to {λ}_{2} T} - {F}_{0 \to {λ}_{1} T}$$

This function determines the fraction of the total emissive power in a wavelength band. F_{0→1.1μm·3000K}=0.34, indicating (1-0.34)=66% of the emissive power resides in wavelength >1.1 μm for a heat source of 3000K. This property, taken together with the transmission curve shows a silicon wafer will not absorb a significant portion of the total emissive energy. An opaque susceptor with high emissivity (ε>0.8), on the other hand, can more readily absorb the incoming radiative energy. According to some embodiments, the susceptor 104 may be formed from graphite (ε>0.8), heavily-doped Si, or other materials having a high ε coating. The VACNTs are known to have high emissivity, an thus may be used to coat a susceptor body in some embodiments.

FIG. 1C shows one embodiment of a heating apparatus 150, sharing many of the aforementioned components of the heating apparatus 100, where like components are labeled the same. In this embodiment, a heat transfer assembly 152 includes a susceptor body 154, and a coating 156, disposed on the susceptor body 154. As shown, the coating 156 is disposed on a second surface, opposite the substrate support surface 109. The coating 156 may have an emissivity greater than 0.8. As such, in some embodiments, the susceptor body need not have a high emissivity, where the emissivity of the susceptor body may be less than 0.8. In other embodiments, the susceptor may be semitransparent as the effective emissivity of the VACNT layer may be >0.9. Nonetheless, absorption of radiation generated the heating assembly 108 may be high, due to the high emissivity of the coating 156 and high emissivity of heat transfer layer 106. Notably, the coating thickness of coating 156 may be less than several micrometers in some embodiments, while the thickness of the susceptor body 154 may be greater than one millimeter, such as up to several millimeters thick.

By using VACNTs as a heat transfer layer 106, between the susceptor 104 and the substrate 110, heat is more efficiently transferred from the susceptor 104 to the substrate 110, especially at relatively lower temperatures, such as below 750 C. This heat transfer can overcome a low thermal contact conductance between susceptor 104 and substrate 110, imposed by vacuum. For example, in known systems, when processing a substrate under vacuum conditions (meaning below a few Torr pressure around the substrate), even with the assistance of backside gas supplied to a substrate holder or susceptor, the thermal conductance between susceptor and substrate does not exceed 1,000 W/m²-K. As a result, a large ΔT (>10° C.) is generally observed for known systems operating under vacuum conditions using a susceptor and substrate, without a VACNT layer.

In particular, arrays (forests) of vertical aligned carbon nanotubes (VACNTs) have exceptional thermal and mechanical properties. These properties render the VACNTs as excellent materials to overcome thermal contact resistance under vacuum. The high thermal conductivities of CNTs, (predictions suggest a value 6,600 W/m-K for single-wall, and 3,000 W/m-K for multiwalled) significantly enhance the heat flow between the substrate 110 and the susceptor 104. Research has shown the thermal conductance of carbon nanotubes may be in the range of 50,000 up to 143,000-250,000 W/m²-K. Such high thermal conductance will render the substrate temperature nearly identical to the temperature of the susceptor, such as within 0.5° C. of the susceptor temperature. Moreover, carbon nanotubes exhibit a degree of mechanical compliance, where the mechanical compliance of carbon nanotubes may allow the heat transfer layer 106 to fill any gaps between substrate 110 and susceptor 104, due to surface roughness, thus providing better thermal path between susceptor 104 and substrate 110.

In operation, the use of the heating apparatus 100 provides for more rapid substrate heating when the heating assembly 108 is turned on or powered. Since the susceptor 104 has a high absorbance of radiation including in the IR range, the use of lamps such as halogen ramps will rapidly and efficiently transfer radiant energy into the susceptor 104. As the susceptor 104 heats up, thermal transfer to the substrate 110 will be very efficient due to the high thermal conductance of the carbon nanotubes.

In other embodiments of the disclosure, enhanced substrate cooling approaches are provided. These approaches may employ apparatus including a cooling block and a heat transfer layer. The cooling block may include a housing having a substrate support surface, and a phase change component, disposed within the housing. The heat transfer layer may include an array of aligned carbon nanotubes, such as those described above.

In these embodiments, the cooling block and heat transfer layer may provide an enhance substrate cooling approach, where, due to carbon nanotube's superb mechanical and thermal properties, a TCC>>10,000 W/m²-K is achieved. This large thermal conductance, combined with the use of a phase change material embedded in a cooling block, may bring a substrate, such as a wafer to room temperature from 150° C. or 500° C. in less than 1 minute while maintaining temperature uniformity <1° C. during cooling.

In various embodiments, the housing of a cooling block may be in the shape of an enclosure containing phase change material (PCM), where a vertical aligned carbon nanotube (VACNTs) coating is disposed on top of the enclosure. The heat transfer layer may be formed wherein the carbon nanotubes are formed as a growing layer of vertically aligned nanotubes on the enclosure or may be formed by applying a pre-formed layer of vertically aligned nanotubes onto the enclosure.

As detailed below, in different embodiments, an enclosure or cooling block containing phase change material may be a stand-alone apparatus, may be mounted onto a cooled structure, such as a water-cooled chamber wall, or may be affixed to a cooled structure such as by contacting a cooled chamber wall through another layer of vertically aligned nanotubes.

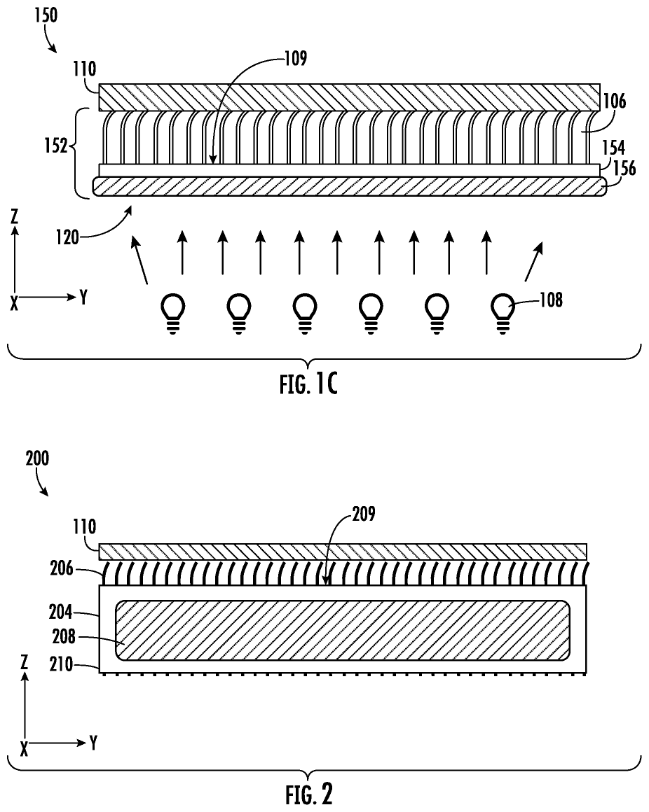

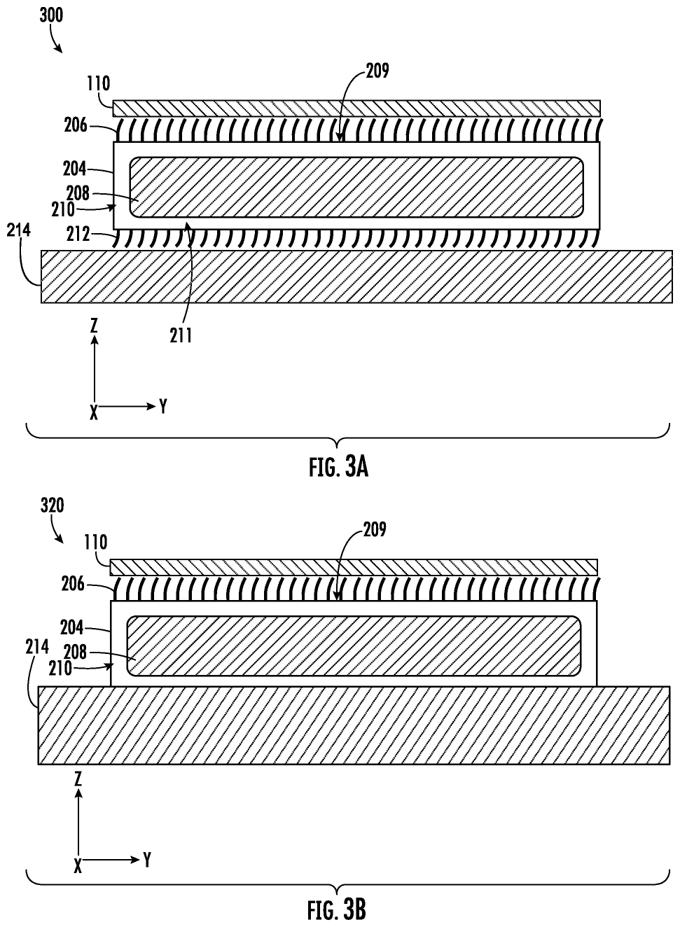

FIG. 2 depicts a cooling apparatus 200, in accordance with further embodiments of the disclosure. FIG. 3A depicts a cooling system 300, in accordance with additional embodiments of the disclosure. FIG. 3B depicts another cooling system, cooling system 320, in accordance with additional embodiments of the disclosure.

In the embodiment of FIG. 2, a cooling block 204 is provided. The cooling block 204 may be a stand-alone structure, capable of being located at any suitable location in a substrate processing apparatus, including an ion implanter, plasma processing device, annealing device, physical vapor deposition apparatus, chemical vapor deposition apparatus, etching apparatus, measurement apparatus, and so forth. In various embodiments, the cooling block 204 may be located in a chamber or enclosure evacuated to a pressure below atmospheric pressure, such as below several Torr, below 1 mTorr, and so forth. As such, the cooling block 204 may be designed to cool a substrate 110 under low pressure or vacuum conditions. In other embodiments, the cooling block 204 may be located in a chamber where an atmosphere of a desired gaseous species is admitted.

As shown in FIG. 2, the cooling block 204 includes a housing 210, and a phase change component 208, disposed within the housing 210. The cooling apparatus 200 further includes a heat transfer layer 206, disposed on a substrate support surface 209, where the substrate support surface 209 extends parallel to a substrate plane (X-Y plane). The heat transfer layer 206 includes an array of vertically aligned carbon nanotubes extending along an alignment direction, perpendicular to the substrate plane, meaning along the Z-axis in this example.

As in previously described embodiments, the nanotubes may be single-walled or multi-walled. Because of high thermal conductance of the arrays of vertically aligned carbon nanotubes, the heat transfer layer 206 rapidly conducts heat from the substrate 110 to the cooling block 204 During a cooling operation, when a substrate 110 is placed on the cooling block 204 sensible heat from the substrate 110 is absorbed by the phase change material. The latent heat of fusion the PCM aids in maintaining a uniform temperature of the cooling block 204, i.e., the melting point of the PCM. In accordance with different embodiments of the disclosure, the PCM material may be selected based on the desired substrate temperature after processing, as well as the latent heat of fusion. For example, to achieve a substrate temperature of 40° C. after cooling, use of a PCM having a melting temperature of approximately 40° C. may be appropriate, since the temperature of the PCM material of the phase change component 208 will not exceed 40° C. until sufficient heat has been absorbed to completely melt the PCM material. Said differently, to ensure 40° C. temperature is rapidly reached, the PCM material may be provided with sufficient mass and sufficiently high latent heat of fusion to ensure the phase change component 208 is not completely melted when sufficient heat is transferred from the substrate 110 to cooling block 204 to cool the substrate from a process temperature to 40° C.

Notably, in some embodiments, the phase change material in cooling block 204 may be replaced by a heat pipe with appropriate heat removal capabilities.

In operation, when a substrate 110 is processed at high temperature at a first location is a system or apparatus, the substrate may be transferred after processing to a position where the substrate 110 is brought into contact with the cooling block 204 and heat transfer layer 206. Once brought into contact with the cooling block 204, including heat transfer layer 206, the substrate 110 will rapidly cool at least to the temperature of the cooling block 204.

Based on the high thermal conductance of aligned carbon nanotubes, an analytical model was developed to predict the time needed to cool the substrate 110 to 30° C. under different conditions, assuming an enclosure temperature of 25° C. Notably, while research has shown the thermal conductance of carbon nanotubes may be in the range of 50,000 up to 143,000-250,000 W/m²-K, more conservative values for thermal conductance are used to illustrate the benefit of a heat transfer layer of vertically aligned carbon nanotubes. Table 1 shows a comparison of cooling cycle duration for cooling a silicon wafer from two different elevated temperatures according to different scenarios. In a radiation-only scenario, the substrate is removed from a heat source and allowed to cool in vacuum by self-radiation. In a load lock cooling scenario, the substrate is placed in a load lock with an atmosphere approximately 1 atm. In the columns for TCC=1,000 W/m²-K, TCC=25,000 W/m²-K, the substrate is instantly placed on the cooling block, such as in the arrangement of FIG. 2. With radiation-only cooling, the cooling cycle is unduly long, 64 min or 76 min for cooling from 150° C. or 500° C., respectively. Cooling in a loadlock is shorter in duration, while still requiring 12 min and 16 min for cooling from 150° C. or 500° C., respectively. In the cooling block arrangement of the present embodiments, even with a very conservative estimate of TCC=1,000 W/m²-K, the substrate is cooled to room temperature in less than 5, or less than 7 seconds, respectively, for 150° C. and 500° C., a drastic improvement comparing with the loadlock cooling. At a plausible rate of 25,000 W/m²-K, the substrate is cooled to room temperature in less than ⅓ second for 150° C. and 500° C., a remarkable result.

TABLE 1
Comparisons of wafer temperatures for different cooling scenarios

| True | | | | |
|---|---|---|---|---|
| wafer | | | | |
| temper- | Radiation- | Cooling in a | (TCC = 1,000 | (TCC = |
| ature | only | load lock | W/m²-K) | 25,000 W/m²-K) |
| 150° C. | 64 min | 12 min | 4.4 sec | 0.29 sec |
| 500° C. | 76 min | 16 min | 6.4 sec | 0.30 sec |

In accordance with various embodiments of the disclosure, the PCM material selected for use in a cooling block may we be either an inorganic or organic material. For scenarios to cool a substrate rapidly to room temperature, one can choose the family of paraffin waxes, which family in general contains different members having melting points in the range of 5° C.−60° C., depending on the exact chemical composition. A short list of related hydrocarbons is shown in II. As shown, the temperature to be reached by a substrate may be controlled by choice of the melting temperature of the PCM material, where a family of materials providing melting point increments as small as 3 degrees are readily available.

TABLE II
Thermal properties of linear hydrocarbons for use as PCM

| | No. of | Melting point | Latent heat |
|---|---|---|---|
| Hydrocarbons | C atoms | (° C.) | (kJ/kg) |
| n-Hexadecane | 16 | 22 | 185.3 |
| n-Heptadecane | 17 | 25 | 176.4 |
| n-Octadecane | 18 | 27.5 | 241.4 |
| n-Nonadecane | 19 | 34.4 | 177.6 |
| n-Eiscosane | 20 | 36.4 | 248 |

As discussed above, cooling of a substrate by the cooling block 204 involves transfer of heat from the substrate at a given initial temperature to the cooling block 204. To cool a 150° C. 300 mm-Si wafer, having a mass of 128 gram, to 25° C., the sensible heat needed to be removed is 11,320 J. To process 25 wafers, 1.6 kg n-Heptadecane (e.g. a Ø300 mm cylinder with a height of 29 mm) is needed. To process more wafers without a hard stop, the amount or size of the PCM material would increase linearly with increased number of wafers. Thus, the embodiment of FIG. 2 may be useful for cooling relatively small batches of wafers, at relatively lower temperatures. In other words, assuming heat is not readily removed from the cooling block 204 in the stand-alone configuration of FIG. 2, once the PCM is entirely melted, the cooling block 204 will no longer be effective in cooling substrates down to the melting temperature of the PCM material, but rather will heat up upon receiving further heat from the substrate 110. Thus, assuming a 300 mm cylinder of 29 mm height represents an upper limit of size for the cooling block 204, the stand-alone configuration of FIG. 2 may be useful for cooling up to the equivalent of 25 Si wafers from 150° C. to 25° C.

For cooling larger numbers of wafers, other embodiments provide configurations where a cooling block is thermally grounded. FIG. 3A depicts a cooling system 300, in accordance with additional embodiments of the disclosure. FIG. 3B depicts another cooling system, cooling system 320, in accordance with additional embodiments of the disclosure. In the configuration of FIG. 3A, the system 300 may include similar components to the cooling apparatus 200, where like components are labeled the same. In this configuration, in addition to the heat transfer layer 206, a second heat transfer layer 212 is provided on a lower surface 211 of the housing 210, and a cooling structure 214 is disposed opposite the lower surface 211. As shown, the second heat transfer layer 212 is disposed in contact with the lower surface 211 and the cooling structure 214. According to various embodiments, the second heat transfer layer 212 includes a second array of aligned carbon nanotubes. Notably, the first heat transfer layer (heat transfer layer 206) and the second heat transfer layer may have a thermal conductance of 50,000 W/m²-K to 250,000 W/m²-K.

In the embodiment of FIG. 3A, the cooling structure 214 may be a cooled chamber wall of a cooling chamber, such as a water-cooled chamber wall. As such, heat may be continuously removed in a manner where the PCM of the cooling block 204 does not completely melt, even when the total heat removed during cooling of a batch of wafers exceeds the amount of heat required to melt the entire amount of PCM material of cooling block 204. In other words, heat may be sunk to the cooling structure 214 continuously so heat initially absorbed in cooling block 204 is removed sufficiently rapidly to prevent complete melting of PCM material. Thus, the system 300 may be appropriate for rapid cooling of large batches of wafers, such as batches of 100 wafers or more. The system 300 also allows the design of the cooling block 204 to be less bulky, since the total volume of PCM material need not be excessively large, since cooling of a wafer is performed one-wafer-at-a-time, where heat may be removed to the cooling structure 214 during wafer cooling and in between time of loading a next wafer.

FIG. 3B depicts another cooling system, cooling system 320, in accordance with additional embodiments of the disclosure. In the configuration of FIG. 3B, the cooling system 320 may include similar components to the system 300, where like components are labeled the same. A difference in this embodiment is the fact the second heat transfer layer 212 is omitted. For example, the cooling block 204 may be directly affixed to a water-cooled chamber wall, where thermal contact is sufficient to remove sufficient heat from the cooling block 204 to allow for continuous operation.

In sum, there are notable advantages of the embodiments of FIGS. 1-3B, including: a first advantage of providing improved performance of vertical aligned carbon nanotubes (VACNTs) as a thermal interface material, for better heat transfer under vacuum or low pressure conditions. A further advantage lies in the thermal heat sink characteristics of the PCM, i.e. energy storage, and temperature uniformity afforded by the combination of rapid heat transfer and high latent heat of fusion of the materials of these embodiments.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize the usefulness is not limited thereto and the present disclosure may be beneficially implemented in any number of environments for any number of purposes.

What is claimed is:

1. A heating system for heating a substrate, comprising:
a susceptor, the susceptor having a substrate support surface; and
a heat transfer layer, disposed on the substrate support surface, the heat transfer layer comprising an array of aligned carbon nanotubes.

2. The heating system of claim 1, wherein the substrate support surface extends parallel to a substrate plane, and wherein the array of aligned carbon nanotubes extend along an alignment direction, perpendicular to the substrate plane.

3. The heating system of claim 1, further comprising a heat source, disposed to heat the susceptor from a side of the susceptor, opposite the substrate support surface.

4. The heating system of claim 3, the heat source comprising an array of lamps.

5. The heating system of claim 3, the heat source comprising a resistive heater.

6. The heating system of claim 1, the heat transfer layer comprising a thermal conductance of 1,000 W/m²-K to 250,000 W/m²-K.

7. The heating system of claim 1, wherein the susceptor comprises an opaque material, having a high emissivity (c), where (ε>0.8).

8. The heating system of claim 7, wherein the susceptor comprises a susceptor body, having an emissivity less than 0.8, and a coating, disposed on the susceptor body, and having an emissivity greater than 0.8.

9. The heating system of claim 8, wherein the coating is disposed on a second surface, opposite the substrate support surface.

10. A cooling apparatus for cooling a substrate, comprising:
a cooling block, the cooling block comprising:
a housing, the housing having a substrate support surface; and
a phase change component, disposed within the housing; and
a heat transfer layer, disposed on the substrate support surface, the heat transfer layer comprising an array of aligned carbon nanotubes.

11. The cooling apparatus of claim 10, wherein the substrate support surface extends parallel to a substrate plane, and wherein the array of aligned carbon nanotubes extend along an alignment direction, perpendicular to the substrate plane.

12. The cooling apparatus of claim 10, the heat transfer layer comprising a thermal conductance of 50,000 W/m²-K to 250,000 W/m²-K.

13. The cooling apparatus of claim 10, the phase change component comprising a paraffin wax having a melting temperature in a range of 5° C.−60° C.

14. A cooling system for cooling a substrate, comprising:
a cooling block, the cooling block comprising:
a housing, the housing having a substrate support surface and a lower surface, opposite the substrate support surface; and
a phase change component, disposed within the housing;
a first heat transfer layer, disposed on the substrate support surface, the first heat transfer layer comprising a first array of aligned carbon nanotubes;
a cooling structure, the cooling structure disposed opposite the lower surface; and
a second heat transfer layer, disposed in contact with the lower surface and the cooling structure, the second heat transfer layer comprising a second array of aligned carbon nanotubes.

15. The cooling system of claim 14, wherein the substrate support surface extends parallel to a substrate plane, and wherein the first array of aligned carbon nanotubes and the second array of aligned carbon nanotubes extend along an alignment direction, perpendicular to the substrate plane.

16. The cooling system of claim 14, the first heat transfer layer and the second heat transfer layer comprising a thermal conductance of 1,000 W/m²-K to 250,000 W/m²-K.

17. The cooling system of claim 14, the phase change component comprising a paraffin wax having a melting temperature in a range of 5° C.-60° C.
